(19) United States
(12) Patent Application Publication
(10) Pub. No.: US 2006/0292836 A1
(43) Pub. Date: Dec. 28, 2006

(54) MANUFACTURING METHOD OF POLYSILICON

(76) Inventor: Yao Peng, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,396

(22) Filed: Aug. 2, 2005

(30) Foreign Application Priority Data
Jun. 28, 2005 (TW) 94121563

(51) Int. Cl. H01L 21/20; H01L 21/84

(52) U.S. Cl. 438/482; 438/486

(57) ABSTRACT

A manufacturing method of polysilicon is provided. First, a substrate is provided, and an amorphous silicon layer is formed on the substrate. Then, a buffer layer is formed on the amorphous silicon layer, and a metal catalysis solution is applied onto the surface of the buffer layer, wherein the metal catalysis solution comprises a solvent and a metal salt. Thereafter, a baking process is performed to remove the solvent of the metal catalysis solution and depositing the metal salt on the surface of the buffer layer. Then, an annealing treatment is performed for diffusing metal ions of the metal salt into the amorphous silicon layer and inducing the amorphous silicon layer to crystallize and become a polysilicon layer. Next, the buffer layer and the metal salt remaining thereon are removed. The method can prevent excess metal silicide or metal atoms in the amorphous silicon layer.

### CROSS-REFERENCE TO RELATED APPLICATION

This application claims the priority benefit of Taiwan application serial no. 94121563, filed on Jun. 28, 2005. All disclosure of the Taiwan application is incorporated herein by reference.

### BACKGROUND OF THE INVENTION

1. Field of the Invention

The present invention relates to a manufacturing method of polysilicon. More particularly, the present invention relates to a manufacturing method of polysilicon associated with the technique of metal induced lateral crystallization (MILC).

2. Description of Related Art

An outcome of the rapid progress in high-tech products is the popularity of video products such as digital video or imaging devices in our daily life. To be useful, these digital video and imaging devices must provide a high-quality display so that a user can operate a controlling device or read some important information disseminated via the display.

At present, liquid crystal displays (LCD) are the most common type of displays in the market with applications in desktop computers, personal computers, game centers and monitors. The principal driving devices for a liquid crystal display (LCD) are thin film transistors (TFT). Because the amorphous silicon layer inside the amorphous silicon thin film transistors can be grown at a relatively low temperature of between 200° C. to 300° C., the amorphous silicon thin film transistors are frequently used in liquid crystal displays. However, the electron mobility of amorphous silicon is lower than 1 cm2/V.s. Hence, amorphous silicon thin film transistor can hardly match the speed desired from a high-speed device. On the other hand, the polysilicon thin film transistor has electron mobility and low temperature sensitivity higher than the amorphous silicon thin film transistor. In other words, the polysilicon thin film transistors are better attuned to high-speed operations. Yet, the process of transforming amorphous silicon into polysilicon layer often requires an annealing temperature in excess of 600° C. Therefore, expensive quartz substrate instead of glass substrate must be used. Moreover, it is difficult to fabricate a quartz substrate with a moderately large size. Hence, the size of a liquid crystal display deploying polysilicon thin film transistors is often limited to between 2 to 3 inches on each side.

To reduce production cost, glass substrates are commonly used for producing liquid crystal displays so that the temperature for fabricating the polysilicon layer must be reduced to below 500° C. Because of this, a number of methods for fabricating low temperature polysilicon layer are developed; among which, the excimer laser annealing (ELA) and the metal induced lateral crystallization (MILC) are the most prominent. Wherein, the metal induced lateral crystallization process relies on the lateral growth of crystals. First, a catalysis metal layer for catalyzing the crystallization of an amorphous silicon layer is formed after the process of depositing amorphous silicon. Thereafter, a low temperature annealing process is performed to produce a polysilicon layer.

The catalysis metal layer adopted in the MILC process provides metal ions diffusing into the amorphous silicon layer as performing the low temperature annealing process and forming metal silicide for inducing amorphous silicon to crystallize. However, since the catalysis metal layer is directly deposited on the surface of the amorphous silicon layer, the metal silicide or the metal atoms formed thereon may be excess. The excess metal silicide or metal atoms may aggravate the problem of current leakage in the polysilicon layer and affect the electrical performance of the polysilicon layer. Certainly, complex process can be adopted to separate the excess metal silicide or metal atoms from the polysilicon layer, but it comes with high manufacturing cost.

### SUMMARY OF THE INVENTION

Accordingly, the present invention is directed to a manufacturing method of polysilicon capable of preventing excess metal silicide or metal atoms in the amorphous silicon layer and improves the electrical performance of the polysilicon layer.

The present invention is also directed to a manufacturing method of polysilicon, which needs no vacuum metal coating apparatus to form the catalysis metal layer, thus the manufacturing cost can be reduced.

The present invention is further directed to a manufacturing method of polysilicon, wherein the amount of the catalysis metal can be modified to form a polysilicon layer with superior quality.

The present invention provides a manufacturing method of polysilicon. First, a substrate is provided, and an amorphous silicon layer is formed over the substrate. Then, a first buffer layer is formed on the amorphous silicon layer, and a metal catalysis solution is applied onto the surface of the first buffer layer, wherein the metal catalysis solution comprises a solvent and a metal salt. Thereafter, the substrate is baked for removing the solvent of the metal catalysis solution and depositing the metal salt on the surface of the first buffer layer. Then, an annealing treatment is performed for diffusing metal ions of the metal salt into the amorphous silicon layer and inducing the amorphous silicon layer to crystallize and become a polysilicon layer. Next, the first buffer layer and the metal salt remaining thereon are removed.

According to an embodiment of the present invention, the thickness of the first buffer layer may be from 100 Angstrom to 1000 Angstrom.

According to an embodiment of the present invention, the first buffer layer may be made of silicon oxide or silicon nitride.

According to an embodiment of the present invention, the metal salt comprises nickel nitrate, aluminum nitrate, or copper nitrate.

According to an embodiment of the present invention, the metal catalysis solution is applied onto the first buffer layer by spin coating or inkjet printing.

According to an embodiment of the present invention, the substrate may be a glass substrate.

According to an embodiment of the present invention, the manufacturing method of polysilicon may further comprise forming a second buffer layer on the substrate before forming the amorphous silicon layer.

According to an embodiment of the present invention, the aforementioned second buffer layer may be made of silicon oxide or silicon nitride.

According to an embodiment of the present invention, the aforementioned second buffer layer may be formed on the substrate by chemical vapor deposition (CVD) or sputtering.

According to an embodiment of the present invention, the amorphous silicon layer and the first buffer layer may be formed by CVD or sputtering.

Since the buffer layer is formed over the amorphous silicon layer first and then the metal catalysis solution is applied onto the buffer layer, direct contact of the catalysis metal and the amorphous silicon is prevented. Therefore, the amount of metal silicide or metal atoms in the formed polysilicon layer can be effectively reduced and the electrical performance of the polysilicon layer can be improved. Moreover, since the catalysis metal is held in solution, modification of the amount of the catalysis metal is permitted for attaining superior reaction effect.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1G schematically illustrate a manufacturing process of polysilicon according to the present invention.

FIGS. 2A to 2H are schematic cross-sectional views showing the progression of steps for fabricating LTPS TFTs in a display region and a peripheral circuit region of a TFT array substrate simultaneously.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

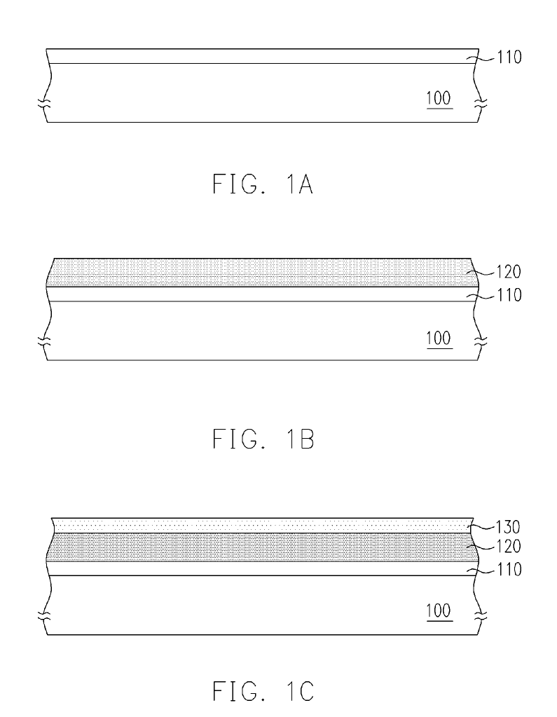

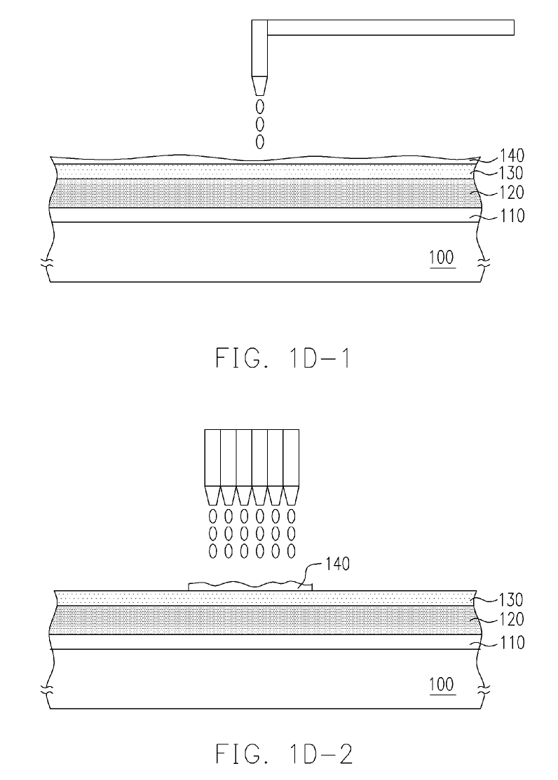

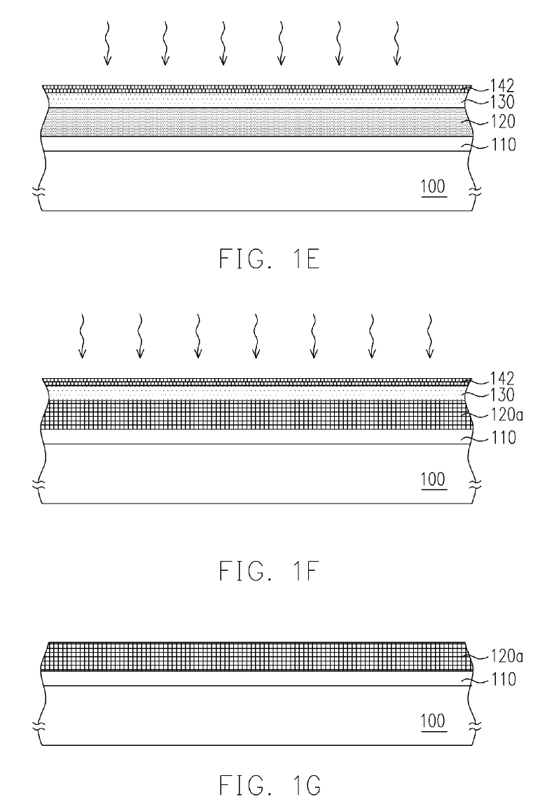

FIGS. 1A to 1G schematically illustrate a manufacturing process of polysilicon according to the present invention.

First, referring to FIG. 1A, a substrate 100 is provided. The substrate 100 may be a glass substrate or other applicable substrates such as a silicon wafer or a plastic substrate. In an embodiment, a buffer layer 110 can be further formed on the substrate 100 by techniques such as CVD or sputtering. The buffer layer 110 may be a stacked layer composed of a silicon nitride layer and a silicon oxide layer, which enhances adhesion between the substrate 110 and a polysilicon layer formed subsequently, and prevents metal ions (e.g. sodium ions) of the substrate 100 from polluting the polysilicon layer.

Then, referring to FIG. 1B, an amorphous silicon layer 120 is formed over the substrate 100 by CVD or sputtering.

Next, referring to FIG. 1C, another buffer layer 130 is formed on the amorphous silicon layer 120. Wherein, the material of the buffer layer 130 may be silicon nitride or silicon oxide, and the preferred thickness of that may be from 100 Angstrom to 1000 Angstrom. An applicable method such as CVD or sputtering for forming the buffer layer 130 can be adopted according thereto. The buffer layer 130 provides a buffer effect between the catalysis metal and the amorphous silicon layer 120 to prevent excess catalysis metal diffusing into the amorphous silicon layer 120. It should be noted that the thickness of the buffer layer 130 in the embodiment is a preferred value, wherein the buffer effect is restricted as the thickness of the buffer layer 130 is smaller than 100 Angstrom. However, if the thickness of the buffer layer 130 is greater than 1000 Angstrom, time for diffusing the catalysis metal into the amorphous silicon layer 120 via the buffer layer 130 will increase. Thus, the thickness of the buffer layer 130 depends on the amount of the catalysis metal in a practical application.

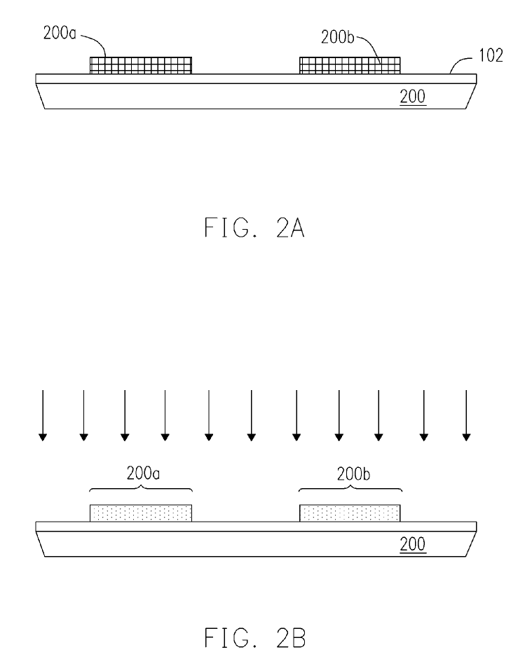

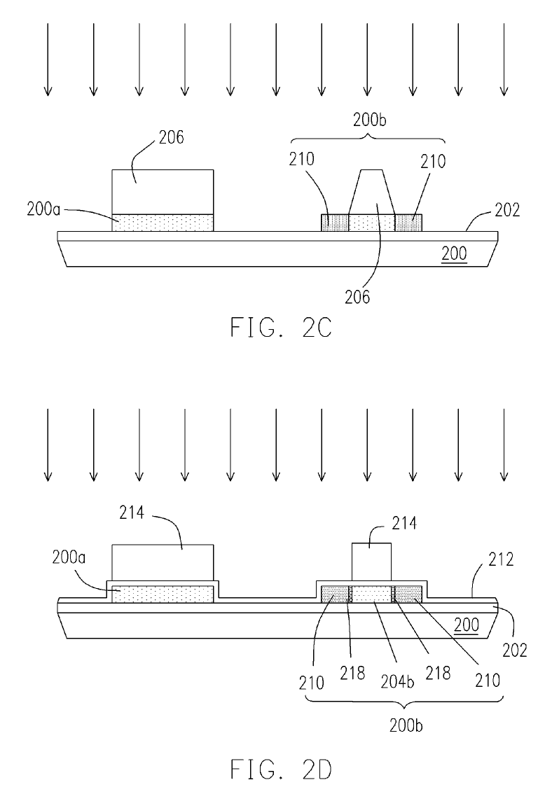

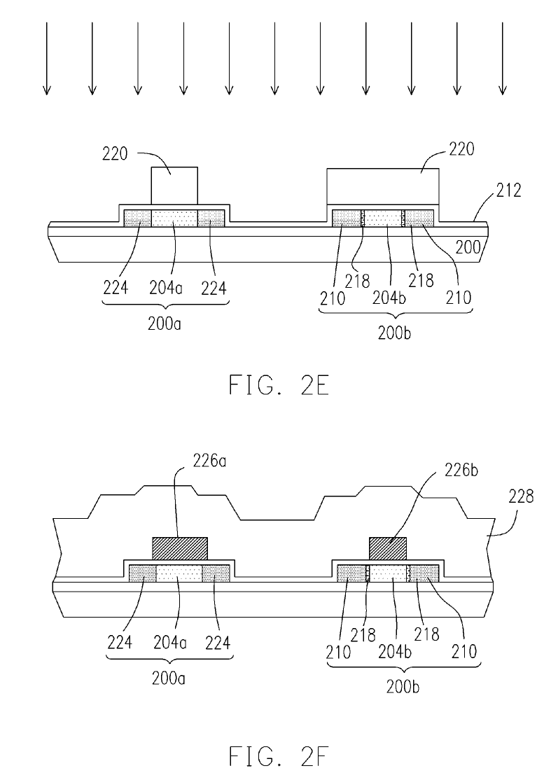

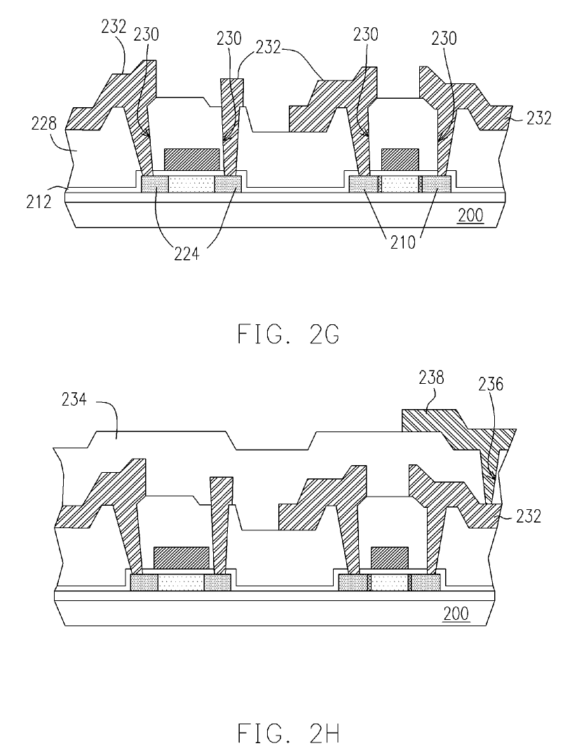

Thereafter, referring to FIGS. 1D-1 and 1D-2, a metal catalysis solution 140 is applied onto the buffer layer 130 by the method such as spin coating or inkjet printing. Wherein, FIG. 1D-1 illustrates applying the metal catalysis solution 140 by spin coating, and FIG. 1D-2 illustrates applying the metal catalysis solution 140 by inkjet printing. The technique of spin coating is adopted for entirely coating the metal catalysis solution 140 on the buffer layer 130. Otherwise, the metal catalysis solution 140 can further be applied onto some specific regions where amorphous needs to be transferred into polysilicon by inkjet printing, wherein the manufacturing process can be simplified, and the waste of the metal catalysis solution can be prevented so as to reduce the manufacturing cost.

In addition, the aforementioned metal catalysis solution 140 may be a solution of nickel nitrate, aluminium nitrate, or copper nitrate, wherein the amount of metal ions (e.g. in the range from thousands to tens of thousands of ppm) can be modified according to the process. Since the metal catalysis solution 140 is adopted in the present invention, the modification of the amount of the metal salt therein is permitted. Therefore, the problem of excess diffusion of the catalysis metal in the amorphous silicon layer 120 can be prevented.

Next, referring to FIG. 1E, a baking process is carried out for removing the solvent of the metal catalysis solution 140. And the metal salt 142 (e.g. nickel nitrate, aluminium nitrate, or copper nitrate) is deposited on the surface of the buffer layer 130.

Then, referring to FIG. 1F, an annealing treatment is performed to diffuse metal ions of the metal salt 142 such as nickel nitrate, aluminium nitrate, or copper nitrate into the amorphous silicon layer 120 via the buffer layer 130. Wherein, a metal silicide is formed in the amorphous silicon layer 120 and induces the amorphous silicon layer 120 to crystallize and become a polysilicon layer 120a.

Thereafter, referring to FIG. 1G, the buffer layer 130 and the metal salt 142 remaining thereon are removed by dry etching or wet etching.

After the manufacture of polysilicon layer is accomplished, processes for forming films can be performed subsequently to form semiconductor devices such as thin film transistors. The process of forming low temperature polysilicon thin film transistors (LTPS TFTs) in a TFT array substrate will be illustrated in the following.

FIGS. 2A to 2H are schematic cross-sectional views showing the progression of steps for fabricating LTPS TFTs in a display region and a peripheral circuit region of a TFT array substrate simultaneously.

First, referring to FIG. 2A, island polysilicon layers 200a and 200b have been formed on the substrate 200. The island polysilicon layer 200a is a section set aside for forming a P-type thin film transistor and the island polysilicon layer 200b is another section set aside for forming an N-type thin film transistor. In the following example, the method for forming a P-type and an N-type thin film transistor simultaneously is described. Obviously, this invention is not limited to the simultaneously fabrication of P-type and N-type thin film transistors.

As shown in FIG. 2B, a channel doping operation is carried out to form a doped region in various island polysilicon layers 200a, 200b.

As shown in 2C, a patterned photoresist layer 206 is formed over the substrate 200 to cover the island polysilicon layer 200a and a portion of the island polysilicon layer 200b so that a portion of the upper surface on each side of the island polysilicon layer 200b is exposed. Thereafter, an n+doping operating is performed to form a doped source/drain region 210 of an N-type thin film transistor on each side of the island polysilicon layer 200b.

As shown in FIG. 2D, the patterned photoresist layer 206 is removed. Thereafter, a gate insulation layer 212 is formed over the island polysilicon layers 200a, 200b and the buffer layer 202. Another patterned photoresist layer 214 is formed over the gate insulation layer 212 to cover the island polysilicon layer 200a and a portion of the island polysilicon layer 200b so that the region close to the doped source/drain region 210 is exposed. Then, an n−doping operation is performed to form lightly doped drain regions 218 and define a channel region 204b between the lightly doped drain regions 218 for the N-type thin film transistor.

As shown in FIG. 2E, the patterned photoresist layer 214 is removed. Another patterned photoresist layer 220 is formed over the gate insulation layer 212 to cover the island polysilicon layer 200b and a portion of the polysilicon layer 200a so that the upper surface on each side of the island polysilicon layer 200b is exposed. Thereafter, a p+doping operation is performed to form doped source/drain regions 224 and define a channel 204a between the doped source/drain region 224 for a P-type thin film transistor.

As shown in FIG. 2F, the patterned photoresist layer 220 is removed and then gates 226a and 226b are formed over the channel regions 204a and 204b respectively. Thereafter, an inter-layer dielectric layer (IDL) 228 is formed over the substrate 200 to cover the island polysilicon layers 200a, 200b and the gates 226a, 226b.

As shown in FIG. 2G, a plurality of openings 230 is formed in the inter-layer dielectric 228 and the gate insulation layer 212 to expose the doped source/drain regions 210 and 224. Thereafter, a plurality of source/drain contact metallic layer 232 is formed over the inter-layer dielectric 228 so that the source drain contact metallic layers 232 are electrically connected to the doped source/drain regions 210 and 224 through the openings 230.

As shown in FIG. 2H, a passivation layer 234 is formed over the substrate 200. Thereafter, an opening 236 is formed in the passivation layer 234 to expose a portion of the source/drain contact metallic layer 232. The passivation layer 234 is a silicon nitride layer, for example. Finally, a pixel electrode 238 is formed over the passivation layer 234 such that the pixel electrode 238 and a portion of the source/drain contact metallic layer 232 are electrically connected through the opening 236. The material of the pixel electrode 238 is, for example, indium-tin oxide (ITO).

In summary, the manufacturing method of polysilicon of the present invention has at least the following characteristics and advantages.
1. The buffer layer is formed on the amorphous silicon layer for reducing the amount of the metal silicide or the metal atoms in the formed polysilicon layer. Thus, the electrical performance of the polysilicon layer and the semiconductor devices formed subsequently can be improved.
2. The adoption of the metal catalysis solution permits modification of the amount of the catalysis metal for attaining superior reaction effect.
3. There needs no vacuum metal coating apparatus to form the catalysis metal layer, thus the manufacturing cost can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing method of polysilicon, comprising:
providing a substrate;
forming an amorphous silicon layer over the substrate;
forming a first buffer layer on the amorphous silicon layer;
applying a metal catalysis solution onto the first buffer layer, wherein the metal catalysis solution comprises a solvent and a metal salt;
baking the substrate for removing the solvent of the metal catalysis solution and depositing the metal salt on the surface of the first buffer layer;
performing an annealing treatment for diffusing metal ions of the metal salt into the amorphous silicon layer and inducing the amorphous silicon layer to crystallize and become a polysilicon layer; and
removing the first buffer layer and the metal salt remaining thereon.

2. The manufacturing method of polysilicon according to claim 1, wherein the thickness of the first buffer layer is from 100 Angstrom to 1000 Angstrom.

3. The manufacturing method of polysilicon according to claim 1, wherein the first buffer layer is made of silicon oxide or silicon nitride.

4. The manufacturing method of polysilicon according to claim 1, wherein the metal salt comprises nickel nitrate, aluminum nitrate, or copper nitrate.

5. The manufacturing method of polysilicon according to claim 1, wherein the metal catalysis solution is applied onto the first buffer layer by spin coating or inkjet printing.

6. The manufacturing method of polysilicon according to claim 1, wherein the substrate is a glass substrate.

7. The manufacturing method of polysilicon according to claim 1, further comprising forming a second buffer layer on the substrate before forming the amorphous silicon layer.

8. The manufacturing method of polysilicon according to claim 7, wherein the second buffer layer is made of silicon oxide or silicon nitride.

9. The manufacturing method of polysilicon according to claim 7, wherein the second buffer layer is formed on the substrate by chemical vapor deposition or sputtering.

10. The manufacturing method of polysilicon according to claim 1, wherein the amorphous silicon layer is formed over the substrate by chemical vapor deposition or sputtering.

11. The manufacturing method of polysilicon according to claim 1, wherein the first buffer layer is formed on the amorphous silicon layer by chemical vapor deposition or sputtering.

12. The manufacturing method of polysilicon according to claim 1, wherein the first buffer layer is removed by dry etching or wet etching.
